(19) United States
(12) Patent Application Publication
(10) Pub. No.: US 2024/0341031 A1
(43) Pub. Date: Oct. 10, 2024

(54) COMPOSITE BOARD MATERIAL AND FLEXIBLE PRINTED CIRCUIT

(71) Applicant: AAC Microtech (Changzhou) Co., Ltd., Changzhou (CN)

(72) Inventors: Guohui Chen, Changzhou (CN); Zhigao Lu, Changzhou (CN)

(21) Appl. No.: 18/525,799

(22) Filed: Nov. 30, 2023

Related U.S. Application Data
(63) Continuation of application No. PCT/CN2023/087096, filed on Apr. 7, 2023.

(51) Int. Cl. H05K 1/03

(52) U.S. Cl. CPC H05K 1/036; H05K 2201/0145; H05K 2201/0154

(57) ABSTRACT

The present disclosure provides a composite board material and a flexible printed circuit. The composite board material includes a first material layer, and two second material layers attached to top surface and bottom surface of the first material layer opposite to each other, respectively. The first material layer is bonded to the two second material layers by adhesive layers. The first material layer includes at least one sublayer, and a material of the at least one sublayer includes polyethylene terephthalate. A material of the two second material layers includes polyimide. In this composite board material, polyethylene terephthalate material functions as inner layer(s), and polyimide material functions as outer layers. In this way, the flatness, hardness, and cost of materials can be balanced, thereby making the obtained flexible printed circuit adaptive to various application scenarios and improving the cost performance of the products.

### CROSS REFERENCE TO RELATED APPLICATIONS

The present application is a continuation of PCT Patent Application No. PCT/CN2023/087096, filed Apr. 7, 2023, which claims priority to Chinese patent application No. 202320760169.1, filed Apr. 7, 2023, each of which is incorporated by reference herein in its entirety.

### TECHNICAL FIELD

The present disclosure relates to the field of electroacoustical technology, and in particular to a composite board material and a flexible printed circuit.

### BACKGROUND

With the continuous development of electronic devices, mobile terminals are becoming more and more light, thin, and flat, and the requirements for materials of flexible printed circuits (FPCs) inside the terminals are also increasing. The materials of existing flexible printed circuits are generally non-metallic materials, including pure PI materials (polyimide), PI adhesive composite materials, multi-layer PI composite materials, pure PET materials (polyethylene terephthalate), PET adhesive composite materials, or the like. The physical properties of PI materials and PET materials are different, including differences in temperature resistance, elastic modulus, flatness, and hardness. The cost of PET and its composite materials is lower than that of PI and its composite materials. Therefore, PI and its various composite materials are suitable for strengthening mid-to-high end products, and PET and its various composite materials are suitable for strengthening low-end products.

However, due to different demands, the FPC industry often requires materials having different physical characteristics for product design, such that the flexible printed circuits have a certain flatness in addition to appropriate modulus and hardness, preferably further have reduced cost. However, existing materials cannot effectively meet the above requirements for flexible printed circuit products.

Therefore, it is necessary to provide a new composite board material and flexible printed circuit to address the above-mentioned problem.

### SUMMARY

The present disclosure aims to provide a composite board material and a flexible printed circuit, which have good modulus, hardness, and flatness performance.

The technical solutions of the present disclosure are described below.

In the first aspect, some embodiments of the present disclosure provide a composite board material, including: a first material layer; and two second material layers attached to top surface and bottom surface of the first material layer opposite to each other, respectively. The first material layer is bonded to the two second material layers by adhesive layers. The first material layer includes at least one sublayer, and a material of the at least one sublayer includes polyethylene terephthalate. A material of the two second material layers includes polyimide.

As an improvement, the adhesive layers are resin adhesive layers.

As an improvement, the first material layer has a composite layer structure, and the composite layer structure includes a plurality of sublayers that one stacks on another, and each two adjacent sublayers of the plurality of sublayers are bonded to each other by one or more respective adhesive layers of the adhesive layers.

As an improvement, the capillary structure has a plurality of cubic through-hole structures, and a diameter of one respective cubic through-hole structure ranges from 80 μm to 300 μm.

As an improvement, each of a thickness of one respective sublayer of the at least one sublayer, a thickness of one respective second material layer of the two second material layers, and a thickness of one respective adhesive layer of the adhesive layers ranges from 5 μm to 200 μm.

As an improvement, the composite board material further includes at least one release layer bonded on a side of one respective second material layer of the two second material layers away from the first material layer by at least one adhesive layer.

As an improvement, the at least one release layer is made of release paper or release film, and a thickness of the at least one release layer ranges from 3 μm to 200 μm.

In the second aspect, some embodiments of the present disclosure provide a flexible printed circuit including the composite board material as described above.

Compared with the related technologies, the composite board material provided in the present disclosure includes a first material layer; and two second material layers attached to top surface and bottom surface of the first material layer opposite to each other, respectively. The first material layer is bonded to the two second material layers by adhesive layers. The first material layer includes at least one sublayer, and a material of the at least one sublayer includes polyethylene terephthalate. A material of the two second material layers includes polyimide. In this composite board material, polyethylene terephthalate material functions as inner layer(s), and polyimide material functions as outer layers. In this way, the flatness, hardness, and cost of materials can be balanced, thereby making the obtained flexible printed circuit adaptive to various application scenarios and improving the cost performance of the products.

### BRIEF DESCRIPTION OF DRAWINGS

In order to illustrate the technical solutions in the embodiments of the present disclosure more clearly, the drawings involved in the description of the embodiments will be briefly described below. It is obvious that the drawings mentioned in the following description are only some embodiments of the present disclosure. For those of ordinary skill in the art, other drawings may be obtained in accordance with these drawings without any inventive effort.

FIG. 1 is a structural schematic diagram of the composite board material according to some embodiments of the present disclosure.

FIG. 2 is a structural schematic diagram of the composite board material having composite PET layers according to some embodiments of the present disclosure.

FIG. 3 is a structural schematic diagram of the composite board material having a release layer according to some embodiments of the present disclosure.

FIG. 4 is a structural schematic diagram of the composite board material having a release layer and composite PET layers according to some embodiments of the present disclosure.

Herein, A denotes first material layer(s), B denotes second material layer(s), C denotes adhesive layer(s), and D denotes release layer(s).

### DETAILED DESCRIPTION OF EMBODIMENTS

In the following, the embodiments of the present disclosure will be illustrated clearly and in detail in conjunction with the accompanying drawings. Obviously, the described embodiments are only a part of the embodiments of the present disclosure, not all of them. Based on the embodiments of the present disclosure, other embodiments obtained by those skilled in the art without inventive efforts all fall within the scope of protection of the present disclosure.

### Embodiment One

The present disclosure provides a composite board material, including: a first material layer; and two second material layers attached to top surface and bottom surface of the first material layer opposite to each other, respectively. The first material layer is bonded to the two second material layers by adhesive layers. The first material layer includes at least one sublayer, and a material of the at least one sublayer includes polyethylene terephthalate (PET). A material of the two second material layers includes polyimide (PI).

In some embodiments, the adhesive layers are resin adhesive layers. In the present disclosure, AD adhesive is taken as an example for description.

In some embodiments, each of a thickness of one respective sublayer of the at least one sublayer, a thickness of one respective second material layer of the two second material layers, and a thickness of one respective adhesive layer of the adhesive layers ranges from 5 μm to 200 μm.

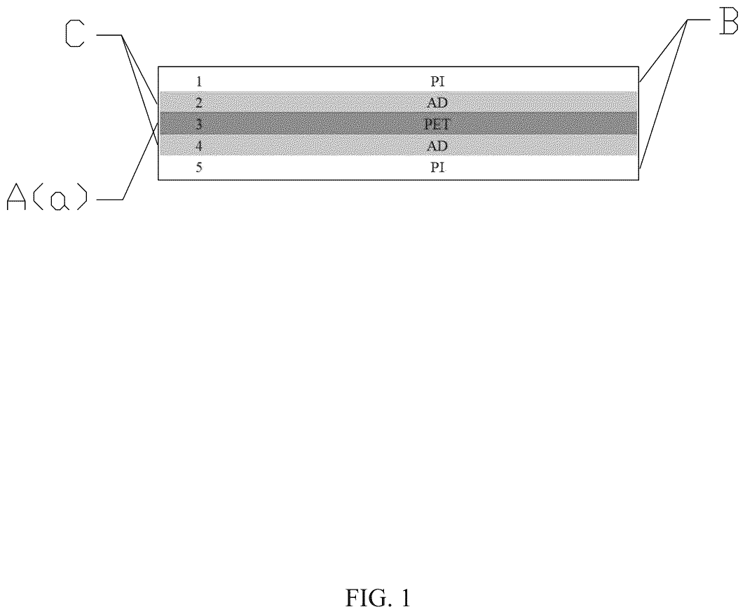

Referring to FIG. 1, FIG. 1 is a structural schematic diagram of the composite board material provided by the present disclosure. In the composite board material, the component of each layer is as follows: 1. PI, 2. AD, 3. PET, 4. AD, 5. PI. That is to say, layers 1 and 5 are the second material layers B, layers 2 and 4 are adhesive layers C, and layer 3 is the first material layer A including one sublayer a. Unless otherwise specified, all embodiments of the present disclosure do not constrain the consistency of the thicknesses of the sublayer a, the second material layers B, and the adhesive layers C.

### Embodiment Two

On the basis of Embodiment One, in some embodiments, the first material layer has a composite layer structure, the composite layer structure includes a plurality of sublayers that one stacks on another, and each two adjacent sublayers of the plurality of sublayers are bonded to each other by one or more respective adhesive layers of the adhesive layers.

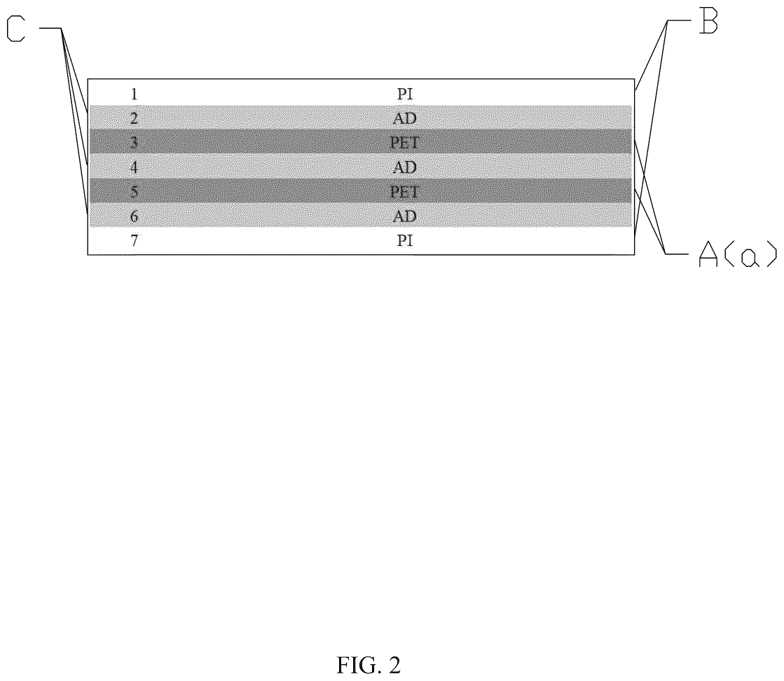

Referring to FIG. 2, FIG. 2 is a structural schematic diagram of the composite board material having composite PET layers provided by the present disclosure. In the composite board material, the component of each layer is as follows: 1. PI, 2. AD, 3. PET, 4. AD, 5. PET, 6. AD, 7. PI. That is to say, layers 1 and 7 are the second material layers B, the first material layer A is a composite layer formed by two sublayers a (3, 5) of PET material bonded to each other by one AD adhesive layer (4), and layers 2, 4 and 6 are the adhesive layers C. A number of the sublayers a of the first material layer A may be determined according to actual requirements.

### Embodiment Three

On the basis of Embodiment One, in some embodiments, the composite board material further includes a release layer bonded on a side of one respective second material layer of the two second material layers away from the first material layer by an adhesive layer, and the release layer is made of release paper or release film. In the present disclosure, release paper (PAPER) is taken as an example for description, and a thickness of the release layer ranges from 3 μm to 200 μm.

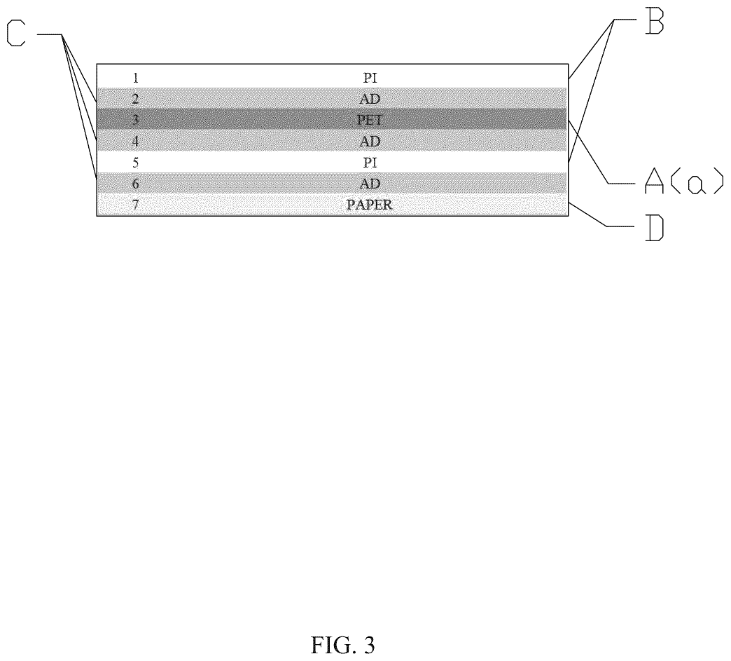

Referring to FIG. 3, FIG. 3 is a structural schematic diagram of the composite board material having the release layer provided by the present disclosure. In the composite board material, the component of each layer is as follows: 1. PI, 2. AD, 3. PET, 4. AD, 5. PI, 6. AD, 7. PAPER. That is to say, layers 1 and 5 are the second material layers B, layers 2, 4 and 6 are the adhesive layers C, layer 3 is the first material layer A, and layer 7 is the release layer D.

### Embodiment Four

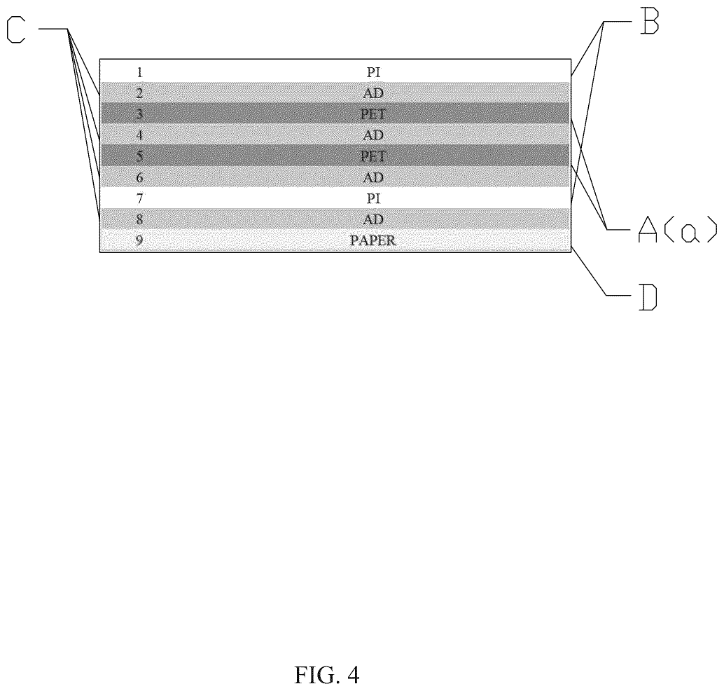

On the basis of Embodiment Two, the release layer also may be bonded to the composite board material having composite PET layers. In some embodiments, referring to FIG. 4, FIG. 4 is a structural schematic diagram of the composite board material having the release layer and the composite PET layers provided by the present disclosure. In the composite board material, the component of each layer is as follows: 1. PI, 2. AD, 3. PET, 4. AD, 5. PET, 6. AD, 7. PI, 8. AD, 9. PAPER. That is to say, layers 1 and 7 are the second material layers B, the first material layer A is a composite layer formed by two sublayers a (3, 5) of PET material bonded to each other by one AD adhesive layer (4), layers 2, 4, 6 and 8 are the adhesive layers C, and layer 9 is the release layer D.

### Embodiment Five

The present disclosure further provides a flexible printed circuit including the composite board material as described above.

Compared with the related technologies, the composite board material provided in the present disclosure includes a first material layer; and two second material layers attached to top surface and bottom surface of the first material layer opposite to each other, respectively. The first material layer is bonded to the two second material layers by adhesive layers. The first material layer includes at least one sublayer, and a material of the at least one sublayer includes polyethylene terephthalate. A material of the two second material layers includes polyimide. In this composite board material, polyethylene terephthalate material functions as inner layer(s), and polyimide material functions as outer layers. In this way, the flatness, hardness, and cost of materials can be balanced, thereby making the obtained flexible printed circuit adaptive to various application scenarios and improving the cost performance of the products.

The above mentioned are only the embodiments of the present disclosure. It should be pointed out that for those skilled in the art, improvements can be made without departing from the inventive concept of the present disclosure, but these improvements are all within the scope of protection of the present disclosure.

What is claimed is:

1. A composite board material, comprising:
a first material layer; and
two second material layers attached to top surface and bottom surface of the first material layer opposite to each other, respectively;
wherein the first material layer is bonded to the two second material layers by adhesive layers;
wherein the first material layer includes at least one sublayer, and a material of the at least one sublayer includes polyethylene terephthalate; and
wherein a material of the two second material layers includes polyimide.

2. The composite board material according to claim 1, wherein the adhesive layers are resin adhesive layers.

3. The composite board material according to claim 1, wherein the first material layer has a composite layer structure; and
wherein the composite layer structure includes a plurality of sublayers that one stacks on another, and each two adjacent sublayers of the plurality of sublayers are bonded to each other by one or more respective adhesive layers of the adhesive layers.

4. The composite board material according to claim 1, wherein each of a thickness of one respective sublayer of the at least one sublayer, a thickness of one respective second material layer of the two second material layers, and a thickness of one respective adhesive layer of the adhesive layers ranges from 5 μm to 200 μm.

5. The composite board material according to claim 1, further including a release layer bonded on a side of one respective second material layer of the two second material layers away from the first material layer by an adhesive layer.

6. The composite board material according to claim 3, further including a release layer bonded on a side of one respective second material layer of the two second material layers away from the first material layer by an adhesive layer.

7. The composite board material according to claim 5, wherein the release layer is made of release paper or release film, and a thickness of the release layer ranges from 3 μm to 200 μm.

8. The composite board material according to claim 6, wherein the release layer is made of release paper or release film, and a thickness of the release layer ranges from 3 μm to 200 μm.

9. A flexible printed circuit, comprising a composite board material, wherein the composite board material includes:
a first material layer; and
two second material layers attached to top surface and bottom surface of the first material layer opposite to each other, respectively;
wherein the first material layer is bonded to the two second material layers by adhesive layers;
wherein the first material layer includes at least one sublayer, and a material of the at least one sublayer includes polyethylene terephthalate; and
wherein a material of the two second material layers includes polyimide.

10. The flexible printed circuit according to claim 9, wherein the adhesive layers are resin adhesive layers.

11. The flexible printed circuit according to claim 9, wherein the first material layer has a composite layer structure; and
wherein the composite layer structure includes a plurality of sublayers that one stacks on another, and each two adjacent sublayers of the plurality of sublayers are bonded to each other by one or more respective adhesive layers of the adhesive layers.

12. The flexible printed circuit according to claim 9, wherein each of a thickness of one respective sublayer of the at least one sublayer, a thickness of one respective second material layer of the two second material layers, and a thickness of one respective adhesive layer of the adhesive layers ranges from 5 μm to 200 μm.

13. The flexible printed circuit according to claim 9, further including a release layer bonded on a side of one respective second material layer of the two second material layers away from the first material layer by an adhesive layer.

14. The flexible printed circuit according to claim 11, further including a release layer bonded on a side of one respective second material layer of the two second material layers away from the first material layer by an adhesive layer.

15. The flexible printed circuit according to claim 13, wherein the release layer is made of release paper or release film, and a thickness of the release layer ranges from 3 μm to 200 μm.

16. The flexible printed circuit according to claim 14, wherein the release layer is made of release paper or release film, and a thickness of the release layer ranges from 3 μm to 200 μm.
